(19) United States
(12) Patent Application Publication
(10) Pub. No.: US 2010/0258190 A1
(43) Pub. Date: Oct. 14, 2010

(54) Organic Photovoltaic Device Having a Non-Conductive Interlayer

(76) Inventors: Jingsong Huang, London (GB); Yim Fun Loo, London (GB); Alan Mosley, Hertfordshire (GB)

Correspondence Address: HICKMAN PALERMO TRUONG & BECKER, LLP, 2055 GATEWAY PLACE, SUITE 550, SAN JOSE, CA, 95110, US

(21) Appl. No.: 12/678,181

(22) PCT Filed: Sep. 11, 2008
(86) PCT No.: PCT/GB08/03087

§ 371 Date: Jun. 28, 2010

(30) Foreign Application Priority Data
Sep. 14, 2007 (GB) 0718011.0

(51) Int. Cl. H01L 31/0256; H01L 51/48; H01L 31/00

(52) U.S. Cl. 136/263; 438/82; 136/252; 257/E51.027; 977/734

(57) ABSTRACT

A photovoltaic device comprising a first electrode, a second electrode, an active layer between the two electrodes and an interlayer between the active layer and at least one of the electrodes. The interlayer is formed from a non-conducting material and has a thickness such that charge carriers can tunnel through. The device shows significantly improved voltage-current characteristics compared to prior art devices and is particularly suitable as a low light level detector.

The present invention relates to a photovoltaic device, a method of fabricating a photovoltaic device and a light detector or solar cell.

A photovoltaic cell is a device that converts optical energy to electrical energy. Uses of photovoltaic cells include generation of electricity as solar cells or in analytical techniques for light detection. The principal mechanism is photoconductivity wherein absorption of a photon results in the generation of an electron-hole pair. The electron and hole separate to become mobile carriers which may be transported through the semiconductor under an electric field. The electric field may arise from a Schottky contact where a built-in potential exists at a metal-semiconductor interface or from a p-n junction between p-type and n-type semiconductive materials. The transport of these carriers enhances the conductivity of the semiconductor. Such devices are usually made from inorganic semiconductors especially silicon due to its high conversion. However, silicon technology has associated high costs and complex manufacturing process steps resulting in devices which are expensive in relation to the power they produce. The development of organic electronics from the eighties of last century has made the organic photovoltaic cell a promised candidate to challenge the dominant position of silicon technology in this field. A photodiode also will act as a source for electrical noise and generate a noise current. The noise current will limit the usefulness of the photodiode at very low light levels where the magnitude of the noise approached that of the signal photocurrent. Due to the nature of organic materials, the noise current in organic photovoltaic cell is relatively high, especially when used in the photoconductive mode. Device architecture has been found to play a crucial role in the performance of organic photovoltaic cells.

Organic photovoltaic cells normally have two kinds of functional materials in the active layer: electron accepting materials and hole accepting materials. Electron accepting material refers to a material which, owing to a higher electron affinity compared to another material, is capable of accepting electrons. Hole accepting material is a material which due to a smaller ionisation potential compared to another material is capable of accepting holes. Similar to their inorganic counterpart, the absorption of light in organic photoconductive materials results in the creation of bound electron-hole pairs. The different feature in organic devices is that the pairs of electron and holes created by the absorption of a photon are only weakly bound. The dissociation of the bound electron-hole pair is facilitated by the interface between electron donor and acceptor. The holes and electrons travel through their respective acceptor materials to be collected at the electrodes. Unlike their counterpart, organic materials usually have much lower carrier mobility, e.g., electron mobility in Silicon at room temperature is about ˜1400 cm²V⁻¹s⁻¹, whereas poly(3-hexylthiophene) has less than 0.1 cm² hole mobility, which is still very high for an organic semiconductor. In order to reduce significant recombination losses of the charge carriers, easier paths to opposite electrodes for electrons and holes are very important. Therefore, the ideal device structure should satisfy two essential requirements: large enough interface of two functional materials and easy pathways of two charge carriers to their collecting electrodes.

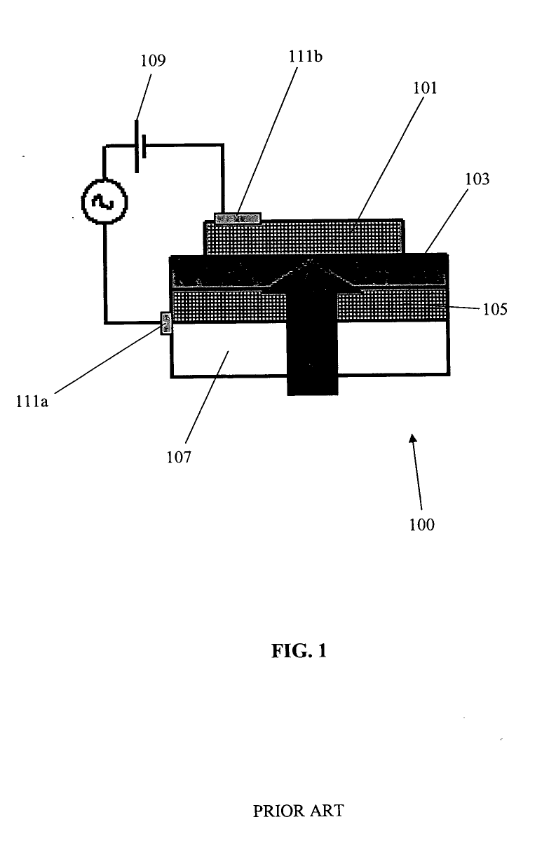

Referring to FIG. 1 there is shown a known organic photovoltaic cell 100 having a photoactive material comprising poly(3-hexylthiophene): 1-(3-Methoxycarbonylpropyl)-1-phenyl-[6.6]C61 (P3HT:PCBM), in which P3HT acts as an electron donor and PCBM acts as the electron acceptor. FIG. 1 shows that the cell comprises, in series: an aluminium electrode 101, a P3HT:PCBM active layer 103; a poly(styrenesulphonate)-doped poly(3,4-ethylenedioxythiophene) (PEDOT:PSS) layer 105; and an ITO substrate 107. The PEDOT:PSS layer 105 and ITO substrate 107 combine to form the anode. The battery 109 is only figurative to show the polarity of the device. The active layer may vary in thickness from a few tens to a few hundreds nanometres or even up to micrometer-scale.

In similar arrangements, C. W. Tang has disclosed two-layer organic photovoltaic cells in U.S. Pat. No. 4,164,431 and U.S. Pat. No. 4,281,053. These were formed in a layer-by-layer fashion, namely, one hole accepting material layer and one electron accepting material layer sandwiched between two electrodes. K. Petritsch et.al (U.S. Pat. No. 6,340,789) fabricated multilayer devices by laminating two components. One component had a first electrode and a first semiconductive layer, another had a second electrode and a second semiconductive layer. They were laminated together by controlled joining of a first semiconductive material and a second semiconductive material. This kind of heterojunction architecture, formed by two neat materials, offers pathways for easier carrier transport. It, however, has a vital drawback: photo-generated excitons have to diffuse toward the interface to get separated. Here, only excitons being created within the exciton diffusion length can contribute to the photocurrent. Unfortunately, the exciton diffusion length in organic materials is often very short. Therefore, this approach is mainly limited by the typically small exciton diffusion length in organic materials.

Moreover, the fabrication of this heterojunction design is limited. When one organic layer is deposited on top of another organic layer, the second layer must be added in such a way that the previously deposited layer is not affected in a detrimental way. Application of this method in polymer electronics is restricted due to its solution process.

The architecture of a trade-off between dissociation of excitons and safe transport of most of the separated carriers was reported recently (T. Tsuzuki, Solar Energy Materials & Solar Cells, 61(2000)1-8; B. Pradhan et al., Synth. Met. 155 (2005) 555 and Appl. Phys. Lett. 85 (2004) 663). This structure has at least one set of three layers between two electrodes. They are a neat electron acceptor layer, a mixture layer of electron acceptor and donor, and a neat electron donor layer. In the mixture layer, the two materials were either mixed uniformly or mixed so as to provide an approximately linear gradient in relative concentration between the two neat layers. This concept has the possibility of enhanced exciton dissociation due to the proximity of donor and acceptor materials in the molecular scale, and provides a better passage for respective charge carriers to the electrodes through the regions of donor and acceptor materials. The presence of neat electron acceptor and donor layers breaks the one component mix extending through the whole device Therefore, high efficiency and low noise device characteristics are expected. However, this structure is very difficult to acheive with polymers.

In a further known arrangement, J. J. M. Halls et al developed an efficient photodiode from interpenetrating polymer networks (U.S. Pat. No. 5,670,791). It describes the formation of a photovoltaic device by depositing a blend comprising electron donor and acceptor polymers between two electrodes. The two different semiconductive polymers form respective continuous networks so that there is a continuous path through each of the semiconductive polymers and a charge carrier within one of the first and second semiconductive polymers can travel between the first and second electrodes without having to cross into the other semiconductive polymer. This so-called bulk-heterojunction architecture provides maximum interface for excitons to separate. However, this concept also has drawbacks. Bulk generated charge carriers need to percolate within the bulk blend toward their specific electrodes. That may lead to reduced charge carrier mobility by the intermixing of two compounds which again limits the range of active layer thickness accessible without significant recombination losses. Additionally, the dark current of these kinds of devices could be high because both electron acceptor and donor make their own continuous pathway from one electrode to another, e.g. creating a parallel single material diode.

The invention is as set-out in the claims. According to a first aspect of the invention, there is provided a photovoltaic device comprising a substrate, a first electrode, an active layer, a second electrode and an interlayer located between and in contact with the active layer and at least one of the electrodes. It is recognised according to the invention that in a two-layered system known from the prior art, it is reasonable to expect the two active components to mix uniformly in all directions in their solid films. Therefore, it is very likely that the two components will make contact directly with the two electrodes respectively, and form their own single diodes. In the photoconductive mode, electrons and holes can choose the easier passages to inject into or extract from the active layer. Here, electrons inject into PCBM rather than P3HT and holes inject into P3HT rather than PCBM. It results in a relatively large shot noise current, leading to current-voltage characteristics unlike the saturation characteristics of an ideal photovoltaic cell. The interlayer thus provides the following advantages: 1) preventing the electron acceptor and/or donor from making their own continuous pathway from one electrode to another thereby preventing them from creating their own parallel single material diodes between the two electrodes; 2) preventing electrons from migrating to the anode and holes migrating to the cathode; 3) to facilitate the collection of electrons at the cathode and holes at the anode; and 4) improves the stability of the device.

The interlayer comprises a non-conductive material. The performance of the device is very sensitive to the thickness of the non-conducting interlayer. Preferably, the thickness of the interlayer is less than 20 nm and more preferably the thickness is less than 10 nm. The thickness of the interlayer is chosen so as to balance a number of factors. In particular, the thickness should be kept as low as possible so as to minimise the increased electrical resistance that the additional layer causes. Furthermore, since the interlayer is non-conducting the charge carriers cannot travel through the interlayer but instead they tunnel through it. If the thickness is too high, charge carriers will not be able to tunnel through and a complete circuit will not be formed.

Embodiments of the invention will now be described by way of non-limiting example only wherein:

FIG. 1 illustrates the architecture of a prior art device;

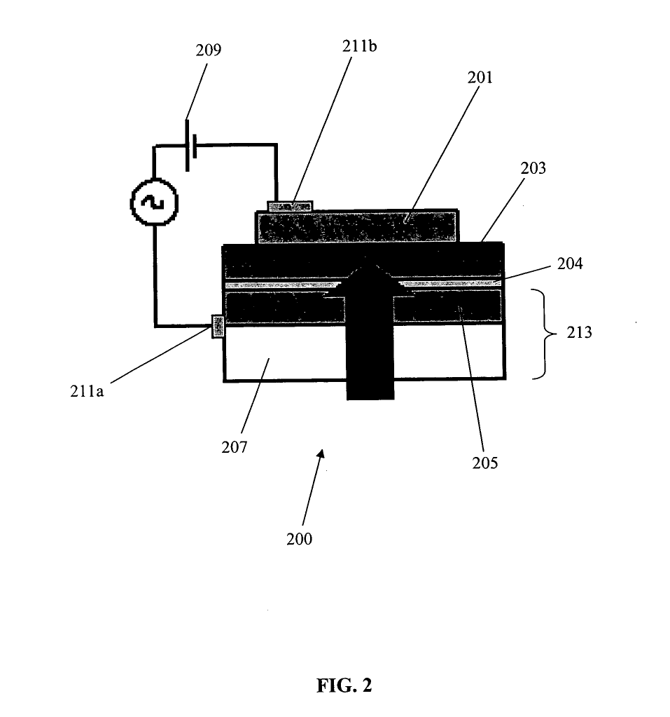

FIG. 2 shows the generic architecture according to embodiments of the present invention;

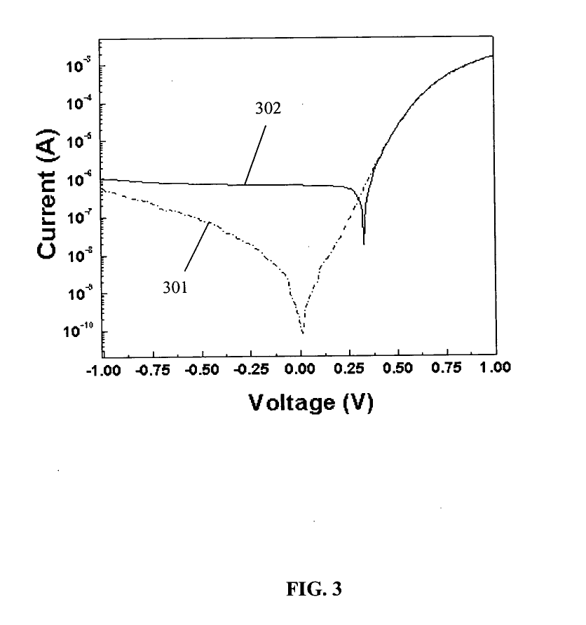

FIG. 3 shows the voltage-current characteristics of the prior art device;

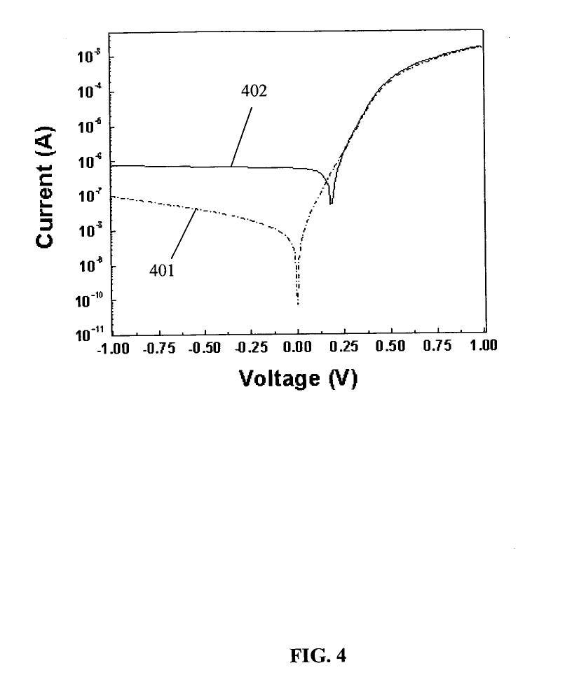

FIG. 4 shows the voltage-current characteristics of a device according to the first embodiment;

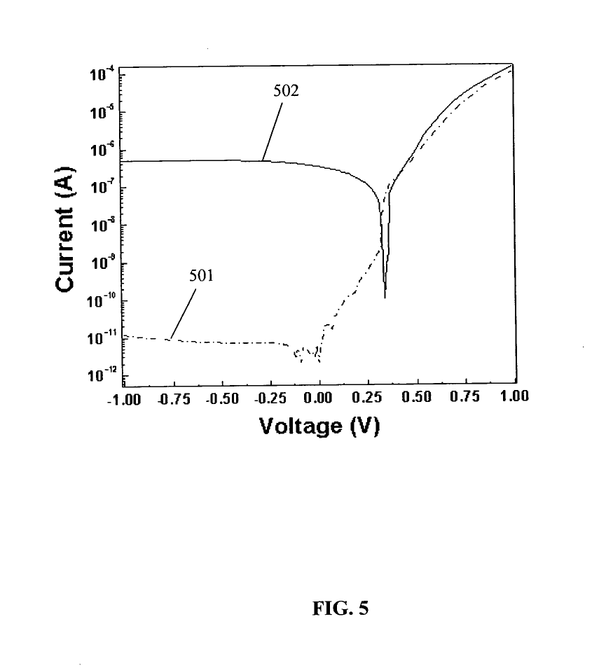

FIG. 5 shows the voltage-current characteristics of a device according to the second embodiment;

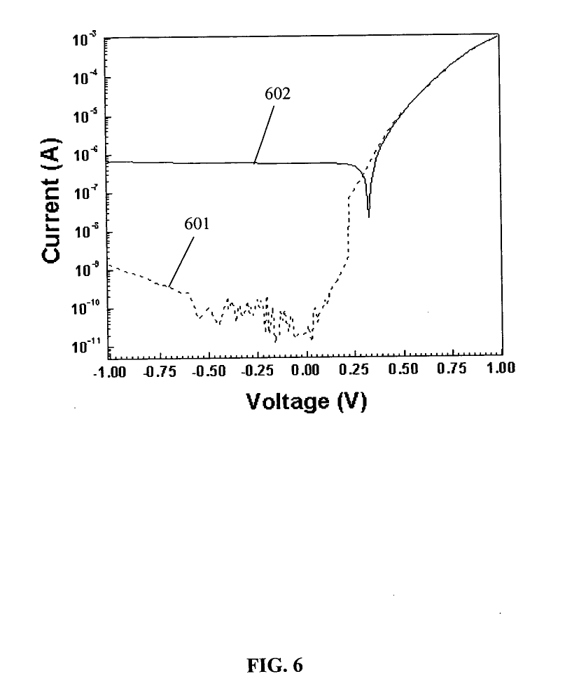

FIG. 6 shows the voltage-current characteristics of a device according to the third embodiment; and

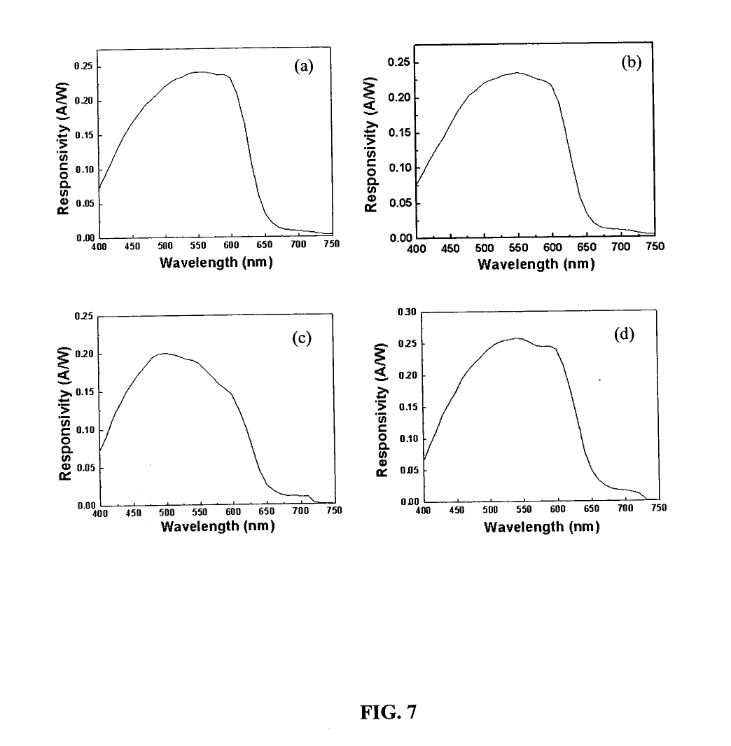

FIG. 7 shows the wavelength-dependent responsivity of the prior art device and device according to the first, second and third embodiments.

In overview, there is provided a photovoltaic device comprising a first electrode, a second electrode, an active layer between the two electrodes and an interlayer between the active layer and at least one of the electrodes. The interlayer is formed from a non-conducting material and has a thickness such that charge carriers can tunnel through. The device shows significantly improved voltage-current characteristics compared to prior art devices and is particularly suitable as a low light level detector.

Referring to FIG. 2, there is shown a first embodiment of the present invention which may be made in accordance with Example 1 set-out below. FIG. 2 shows a photovoltaic cell 200 comprising, in series: an aluminium electrode 201; an active P3HT:PCBM layer 203;

an interlayer 204 of polymethyl methacrylate (PMMA); and a second electrode 213 comprising a PEDOT:PSS layer 205 and an ITO substrate 207. The battery 209 is only figurative to show the polarity of the device. The interlayer of PMMA is typically less than 20 nm thick, preferably less than 10 nm. In alternative embodiments not shown, the interlayer 204 may be between the aluminium electrode 201 and the active layer 205 or between both electrodes 201, 213 and the active layer 203.

In the following illustrative example, all devices are tested in nitrogen at room temperature. The current-voltage characteristics are measured using a Keithley 6517A Electrometer/High Resistance Meter. CM110 1/8 m Monochromator as the light source for photocurrent measurements.

Referring to FIG. 3, there is shown the voltage-current characteristics of the device without an interlayer under dark (plot 301) and light conditions (plot 302). In light conditions (plot 302), the photocurrent is taken under illuminating light of 600 nm with power intensity of 62 μW/cm².

FIG. 4 shows the voltage-current performance achieved with the photovoltaic cell according to the first embodiment wherein the interlayer is PMMA. Plot 401 shows the device performance in light conditions and plot 402 under dark conditions. Plots 401 and 402 are made under the same conditions as plots 301 and 302.

In a second embodiment, which may be made in accordance with Example 2 set-out below, the interlayer 204 comprises, instead, calcium oxide (CaO) and in a third embodiment, made in accordance with Example 3 below, the interlayer 204 is silicon monoxide (SiO).

FIG. 5 shows the voltage-current characteristics obtained using the device in accordance with the second embodiment. These results were obtained under the same conditions described with respect to FIGS. 3 and 4. Referring to FIG. 5, plots 501 and 502 show the dark and light currents respectively of a device according to the second embodiment.

Likewise, FIG. 6 shows the voltage-current characteristics of the device according to the third embodiment. Referring to FIG. 6, plots 601 and 602 show the dark and light currents respectively of a device according to the third embodiment.

FIGS. 7a, 7b, 7c and 7d show the responsivity (Amps per Watt) of the prior art device, the first, second and third embodiments respectively. By comparing FIGS. 7a, 7b, 7c and 7d it can be seen that the presence of the thin interlayer does not substantially affect the responsivity.

It is believed that the closeness of the packing structure of the interlayer affects the maximum thickness that the charge carriers can tunnel through the interlayer. For example, organic materials generally have a relatively loose packing structure and, thus, the charge carriers can tunnel through more material than an inorganic material, for example.

Advantageously, the inert nature of the interlayer improves device stability. A non-conducting material such as used in the interlayer, usually has wide energy gap, for example greater than 4 eV, and a high transparency to visible light. This makes embodiments of the present invention particularly suitable for solar cell application, and visible light detectors.

As the skilled reader will understand, the interlayer could be any non-conductive interlayer such as an organic non-conjugated material, an inorganic dielectric or an active metal which can be converted to a dielectric, by oxidation for example. The interlayer according to any of the embodiments may be arranged between either or both electrodes and the active layer.

The suitability of a particular non-conducting interlayer as the interlayer depends on many properties of the material such as: the optical absorption; the chemical interaction with other layers; the material fluorescence; and optical interaction with the other layers. The choice of material may depend on the specific application of the photovoltaic device.

The active layer in accordance with embodiments of the present invention may comprise any electron accepting material, such as a fullerene, and any electron donating material, such as a conjugated polymer, for example polythiophene.

As the skilled person will understand, any transparent electrode is suitable such as one formed from a layer of transparent conductive oxide, such as indium tin oxide, and a layer of a conductive organic material, such as PEDOT:PSS. Furthermore, the skilled person will understand the second electrode may be formed from any metal, such as aluminium or silver, or a combination of two or more metals, such as calcium and aluminium or calcium and silver or lithium fluoride and aluminium or lithium fluoride and silver.

The substrate may be any suitable material such as glass, for example borosilicate glass or sodalime glass, or plastic.

Embodiments of the present invention provide an improved low light level polymer-based detector with reduced dark current. Experiments show that the dark current is significantly reduced by using the improved construction defined herein. The device may also be used as a solar cell owing to the suitable band gap provided by the interlayer.

The invention will now be illustrated by reference to one or more of the following non-limiting examples:

### EXAMPLE 1

### Device Made with PMMA Interlayer

All the devices according to embodiments of the present invention are fabricated on the pre-patterned indium-tin-oxide (ITO) glass substrates. The fabrication processes of the control device are described as following. The substrates are firstly carefully cleaned in ultrasonic bath of acetone and isopropanol for 15-20 minutes twice each in this sequence.

Then, they are cleaned in isopropanol vapour, and dried properly on hotplate at a temperature above 100° C. This is followed by oxygen plasma treatment (for the embodiment here, the condition is at 100 W for 2.5 minutes). 50 nm thick Baytron P grade poly(styrenesulphonate)-doped poly(3,4-ethylenedioxythiophene) (PEDOT:PSS) is spin coated on the plasma treated ITO glass substrates and annealed in air at 140° C. for 30 minutes. A 10 nm thick PMMA film is deposited from xylene solution and annealed in nitrogen (or glovebox filled with nitrogen) at 180° C. for 15 minutes. The active layer is 165 nm thick regioregular poly(3-hexylthiophene): 1-(3-Methoxycarbonylpropyl)-1-phenyl-[6.6]C61 (P3HT:PCBM) (1:1 wt. % in chlorobenzene) spin-coated in air and annealed at 50° C. for 2 hours in nitrogen (or glovebox filled with nitrogen). Then, top contact, 100nm-thick aluminium electrode is thermally deposited at a pressure of at least 8×10⁻⁶ mbar through a shadow mask, defining the active device area of 0.045 mm². Finally, the post annealing process of the devices is carried out on the hotplate in nitrogen (or glovebox filled with nitrogen) at 140° C. for 1 hour.

The first example may provide a number of advantages in the fabrication process and resulting assembly. Firstly, the interlayer may be insoluble after it is formed on the PEDOT:PSS such that it is not damaged during the (solution) process whereby the active layer is deposited. Secondly, the method in accordance with the first example is very straightforward. Thirdly, the method is less likely to introduce contaminates than prior art methods using doping and treatment at a later stage of the process.

### EXAMPLE 2

### Device Made with SiO Interlayer

The fabrication process is: after PEDOT:PSS deposited as described in Example 1, a 1 nm SiO layer is thermally deposited on top of PEDOT:PSS layer in the vacuum chamber. The other steps are the same as described in Example 1

### EXAMPLE 3

### Device Made with CaO Interlayer

The fabrication process is: after PEDOT:PSS deposited as described in Example 1, a 1 nm Calcium layer is thermally deposited on top of PEDOT:PSS layer in the vacuum chamber. The film is then exposed to air for 20 minutes before depositing the next layer. The other steps are the same as described in Example 1.

1. A photovoltaic device comprising:
a substrate;
a first electrode;
a second electrode;
an active layer arranged between the first and second electrodes; and
a non-conducting interlayer arranged between the active layer and at least one of the electrodes.

2. A device as claimed in claim 1 wherein the interlayer comprises a material selected from the group comprising PMMA, SiO and CaO.

3. A photovoltaic device as claimed in claim 1 comprising a first interlayer arranged between the first electrode and the active layer and a second interlayer between the active layer and second electrode.

4. A photovoltaic device as claimed in claim 3 in which the first interlayer comprises a material selected from the group comprising PMMA, SiO and CaO.

5. A photovoltaic device as claimed in claim 3 in which the second interlayer comprises a material selected from the group comprising PMMA, SiO and CaO.

6. A device as claimed in claim 1 in which the thickness of the interlayer(s) is no more than 20 nm, preferably no more than 10 nm.

7. A device as claimed in claim 1 wherein the active layer comprises a mixture of two or more active materials.

8. A device as claimed in claim 1 wherein the active layer comprises a mixture of an electron accepting material and an electron donating material.

9. A device as claimed in claim 8 where in the electron accepting material comprises a fullerene.

10. A device as claimed in claim 8 wherein the electron donating material comprises a conjugated polymer.

11. A device as claimed in claim 10 wherein the conjugated polymer comprising the electron donating material comprises polythiophene.

12. A device as claimed in claim 7 in which the active layer comprises a mixture of P3HT and PCBM.

13. A device as claimed in claim 12 in which the ratio of P3HT to PCBM in the active layer is 1:1.

14. A device as claimed in claim 1 in which the first electrode is transparent and formed from a layer of a transparent conductive oxide and a layer of a transparent conductive organic material.

15. A device as claimed in claim 14 in which the transparent conductive oxide comprises indium tin oxide

16. A device as claimed in claim 14 wherein the conductive organic material comprises PEDOT:PSS.

17. A device as claimed in claim 1 in which the second electrode is formed from at least one metal.

18. A device as claimed in claim 17 in which the at least one metal comprises aluminium or silver.

19. A device as claimed in claim 1 in which the second electrode is formed from two or more layers.

20. A device as claimed in claim 19 in which the layers are calcium and aluminium or silver.

21. A device as claimed in claim 19 in which the layers are lithium fluoride and aluminium or silver.

22. A device as claimed in claim 1 in which the substrate is a glass.

23. A device as claimed in claim 22 in which the glass is borosilicate or sodalime glass.

24. A device as claimed in claim 1 wherein the substrate is a plastic.

25. A device as claimed in claim 24 in which the plastic is PET.

26. A device as claimed in claim 1 wherein the device is a low light level detector.

27. A method of fabricating a photovoltaic device comprising the steps of:
coating a transparent substrate with an electrode material;
coating the first electrode with at least one active material;
depositing a non-conducting interlayer material on the at least one active material;
depositing a second electrode on the interlayer; and
annealing the device.

28. A method of fabricating a photovoltaic device comprising the steps of:
coating a transparent substrate with an electrode material;
depositing a non-conducting interlayer material on the electrode material;
coating the interlayer with at least one active material;
depositing a second electrode on the active layer; and
annealing the device.

29. A method according to claim 27 further comprising the step of applying a coating of a second non-conducting interlayer.

30. A method according to claim 27 wherein the transparent electrode comprises a layer of Indium Tin Oxide and a layer of PEDOT:PSS.

31. A method according to claim 27 wherein the active material comprises a mixture of P3HT and PCBM.

32. A method according to claim 27 wherein the interlayer comprises one or more of PMMA, SiO and CaO.

33. A method according to claim 27 wherein the second electrode comprises aluminium or silver.

34. A solar cell comprising a photovoltaic device according to claim 1.
